(19) United States
(12) Patent Application Publication
(10) Pub. No.: US 2010/0116332 A1
(43) Pub. Date: May 13, 2010

(54) TRANSPARENT SUBSTRATE PROVIDED WITH AN IMPROVED ELECTRODE LAYER

(75) Inventors: Guillaume Counil, Aubervilliers (FR); Michele Schiavoni, Paris (FR); Fabrice Abbott, Vienne (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, Courbevoie (FR)

(21) Appl. No.: 12/598,042

(22) PCT Filed: Apr. 28, 2008
(86) PCT No.: PCT/FR08/50768

§ 371 Date: Dec. 23, 2009

(30) Foreign Application Priority Data
May 4, 2007 (FR) 0754875

(51) Int. Cl. H01L 31/00; G03F 7/20; B29C 59/02; B32B 3/26; G02B 1/11

(52) U.S. Cl. 136/256; 430/311; 264/293; 428/164; 428/163; 428/162; 359/601

(57) ABSTRACT

This substrate, having a glass function, is combined with a textured electrode comprising at least one transparent conductive layer based on one or more metal oxides, said layer being covered with at least one functional layer of an element capable of collecting light, and is covered with an interface layer having a textured part comprising a repetition of periodic or aperiodic features in relief.

The present invention relates to an improvement made to a transparent substrate, especially made of glass, which is provided with an electrode. This conductive substrate is more particularly intended for forming part of solar cells. It is used especially as the “front face” of a solar cell, that is to say the face that will be directly exposed to the solar radiation to be converted to electricity.

The invention is especially applicable to solar cells of the amorphous or microcrystalline Si type, the structure of which is briefly recalled.

In general, this type of product is sold in the form of solar cells mounted in series between two, possibly transparent, rigid substrates, the front face of which is made of glass. This type of cell is described in German application DE 10 2004 046 554.1.

It is the assembly comprising substrates, polymer and solar cells that is denoted by and sold as a “solar module”.

The invention therefore also relates to said modules.

It is known that when solar modules are not sold by the square meter but by the electric power delivered, each percent in additional efficiency increases the electrical performance, and therefore the price, of a solar module of given dimensions, each percent efficiency gained, for a given solar module technology, being above all dependent on a gain obtained in light transmission within the substrate combined with said cell.

French patent FR 2 832 706 teaches a substrate having a glass function, which is provided with an electrode comprising at least one transparent conductive layer based on one or more metal oxides, this electrode having the particular characteristic of having RMS roughness that varies from a few nanometers to a few tens of nanometers.

Although this substrate with a textured electrode, when it is positioned in the immediate vicinity of an element capable of collecting light (for example a photovoltaic cell or a solar collector) fulfills its function and ensures that a useful energy conversion efficiency is obtained, the inventors have noticed that the diffusion of the source of light within the substrate toward a functional layer of the element capable of collecting light could be further improved.

The object of the invention is therefore to seek means for improving the photoelectric conversion efficiency of these modules, which means relate more specifically to the abovementioned “front” glass plates provided with electrodes. What are sought are means that are simple to implement on an industrial scale and do not upset the known structures and configurations of this type of product.

A first subject of the invention is a substrate having a glass function, combined with a textured electrode comprising at least one transparent conductive layer based on one or more metal oxides, said layer being covered with at least one functional layer of an element capable of collecting light, characterized in that the substrate is covered with an interface layer having a textured part comprising a repetition of periodic or aperiodic features in relief.

Within the invention, the electrode is referred to by the abbreviation TCO (Transparent Conductive Oxide) and is widely used in the solar cell field and in electronics.

Within the invention, the term “functional layer” is defined as any thin layer based on a material allowing light energy to be converted to electrical energy or thermal energy within an element capable of collecting light (for example a solar or photovoltaic cell or a solar collector). The materials in question for solar cells may conventionally be amorphous silicon, microcrystalline silicon or layers based on cadmium telluride (CdTe).

If this surface texturing has particular specifications, what will be obtained is antireflection effect between the two media surrounding the interface layer.

Moreover, by texturing the surface at the interface layer, greater diffusion of the incident light is obtained between the interface layer and the materials that flank it, the light being “obliged” to follow a very much longer path through the solar cell.

By thus extending the optical path, the chances of light absorption by the active elements of the cell are increased and, in the end, the photoelectric conversion factor of the solar cell is increased. Thus, there is better light trapping.

In preferred embodiments of the invention, one or more of the following arrangements may optionally be furthermore employed:
the interface layer is located on the rear face of the substrate and has a textured part that comprises a repetition of periodic or aperiodic features in relief, of pitch w and height h satisfying the following relationships: w≦λ, preferably w≦λ/2 and more preferably w≦λ/4; and h≧λ/4, preferably h≧λ and more preferably h≧2λ, where λ falls within the solar spectrum and is located at the maximum energy conversion efficiency of the solar cell;
the interface layer is located on the rear face of the substrate and has a textured part that comprises a repetition of periodic or aperiodic features in relief, of pitch w and height h satisfying the following relationships: λ/4≦w≦2λ; and h is between 20 nm and 1 μm, preferably between 30 nm and 500 nm and more preferably h is between 50 nm and 200 nm, where λ is located at a wavelength at which the solar spectrum has a large amplitude but the conversion efficiency of the cell is not its optimum;
the conductive layer is deposited on the interface layer;
the interface layer is located on the front face of the substrate and has a textured part that comprises a repetition of periodic or aperiodic features in relief, of pitch w and height h satisfying the following relationships: λ/4≦w≦2λ; and h is between 20 nm and 1 μm, preferably between 30 nm and 500 nm and more preferably h is between 50 nm and 200 nm, where λ is located at a wavelength at which the solar spectrum has a large amplitude but the conversion efficiency of the cell is not its optimum;
the interface layer has a refractive index close to that of the substrate;
the interface layer has a refractive index n≦n_{substrate} if the interface layer is placed on the front face of the substrate;
the interface layer has an index n such that n_{substrate}≦n≦n_{TCO} if the interface layer is placed between the substrate and the conductive layer;
the conductive layer conforms to the interface layer;
the conductive layer has a different roughness from that of the interface layer;
the interface layer is located on the rear face of the substrate and has a textured part which comprises a repetition of periodic or aperiodic features, of pitch w substantially close to 300 nm, for which it has a combination of an antireflection effect for a first wavelength range and a light trapping effect for a second wavelength range;
the features in relief comprise parallel lines;
the features in relief comprise nonparallel lines and/or studs;
the textured surface is obtained by embossing a sol-gel or polymer layer; and
the textured surface is obtained by a photolithography technique.

Other characteristics, details and advantages of the present invention will become more clearly apparent on reading the following description, given by way of purely nonlimiting illustration and with reference to the appended figures in which:

FIG. 1 is a cross-sectional view of a solar cell incorporating a substrate by the implementation of the invention according to a first embodiment, the interface layer being positioned on the rear face of the substrate;

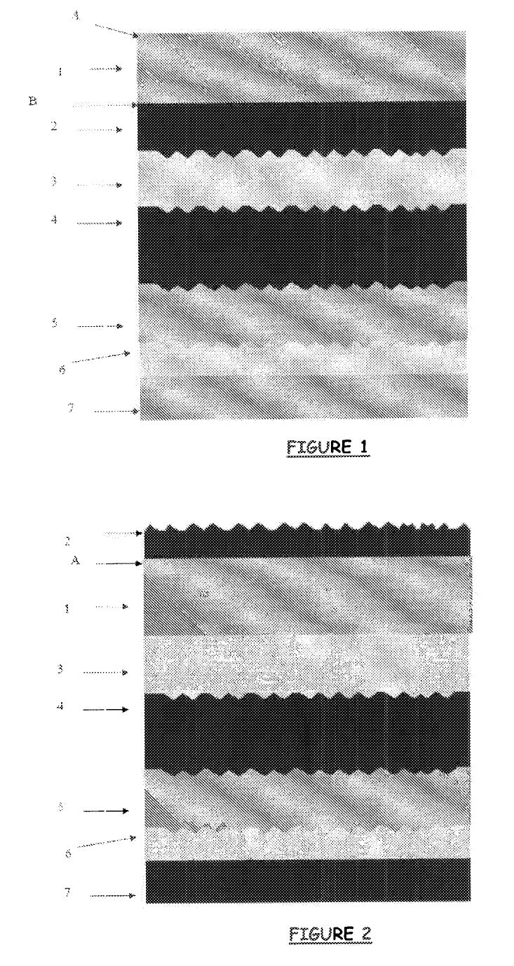

FIG. 2 is a cross-sectional view of a solar cell incorporating a substrate by the implementation of the invention according to a second embodiment, the interface layer being positioned on the front face of the substrate;

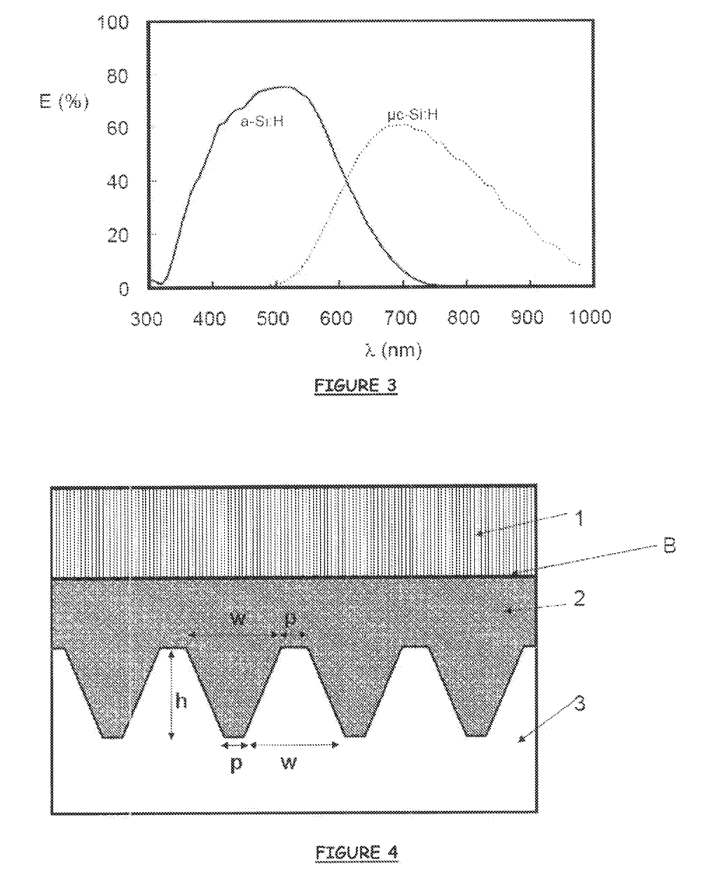

FIG. 3 illustrates the energy conversion efficiencies (E/λ) of two typical photovoltaic cells (amorphous Si and microcrystalline Si) as a function of the wavelength of the light;

FIG. 4 illustrates a first embodiment variant of the invention with an antireflection effect;

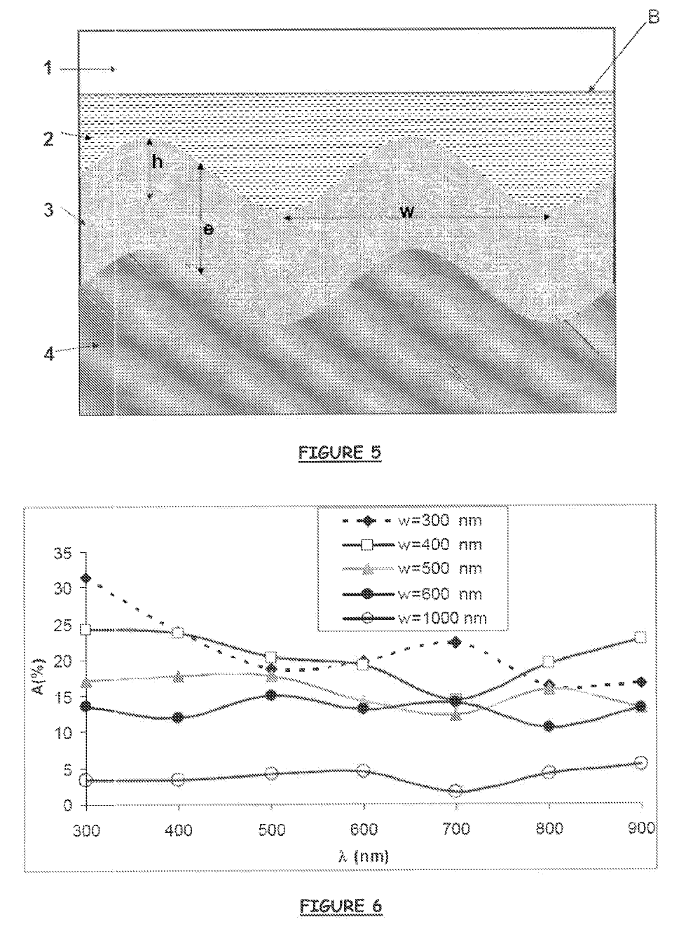

FIG. 5 illustrates a second embodiment variant of the invention with a light-trapping effect; and

FIG. 6 illustrates the optical path as a function of the wavelength for various pitch values.

FIG. 1 shows an element capable of collecting light (a solar or photovoltaic cell) incorporating a substrate according to the invention.

The transparent substrate 1 having a glass function may for example be made entirely of glass. It may also be made of a thermoplastic polymer such as a polyurethane or a polycarbonate or a polymethyl methacrylate.

Most of the mass (i.e. at least 98% by weight) or even all of the mass of the substrate having a glass function is made of material(s) having the best possible transparency and preferably having a linear absorption of less than 0.01 mm⁻¹ in that part of the spectrum useful for the application (solar module), generally the spectrum ranging from 380 to 1200 nm.

The substrate 1 according to the invention may have a total thickness ranging from 0.5 to 10 mm when it is used as protective plate for a photovoltaic cell of various technologies (amorphous silicon, microcrystalline silicon). In this case, it may be advantageous to make this plate undergo a heat treatment (for example of the toughening type).

Conventionally, the front face of the substrate, directed toward the light rays (i.e. the external face) is denoted by A and the rear face of the substrate, directed toward the rest of the layers of the solar module (i.e. the internal face) is denoted by B.

An interface layer 2 is deposited on face B of the substrate. This interface layer 2 is obtained by spin coating, flow coating, spray coating or screen-printing technique, or by any other liquid phase deposition technique for depositing a thin layer, and is based on a polymer or a sol-gel.

The sol-gel layers that can be used are in general liquid layers of a mineral oxide precursor such as SiO₂, Al₂O₃, TiO₂ etc., for example dissolved in a water/alcohol mixture. These layers harden on drying, with or without auxiliary heating means. As SiO₂ precursor, we mention tetraethoxysilane (TEOS) and methyltriethoxysilane (MTEOS). Organic functional groups may be included in these precursors and in the silica finally obtained. For example fluorosilanes have been described in document EP 799 873 for obtaining a hydrophobic coating.

Among the polymers, the following may be mentioned:
polyethylene terephthalate (PET);
polystyrene;
polyacrylates, such as polymethyl methacrylate, polybutyl acrylate, polymethacrylic acid, poly(2-hydroxy-ethyl methacrylate) and copolymers thereof;
epoxy polyacrylates and polymethacrylates;
urethane polyacrylates and polymethacrylates;
polyimides, such as polymethylglutarimide;
polysiloxanes, such as polyepoxysiloxanes;
polyvinyl ethers;
poly(bisbenzocyclobutenes), etc.

by themselves or as copolymers or blends of several of them.

Said features are then produced on the surface of this interface layer 2, either by an embossing technique or by photolithography technique or by any other texturing technique (chemical etching, transfer laser ablation, ion exchange, photorefractive or electrooptic effect).

The embossing process consists in structuring a portion of the surface of the substrate having a glass function, by forming a grating of features with submillimeter-scale characteristic dimensions, the surface structuring by plastic or viscoplastic deformation being carried out by contact with a structured element, called a mask, and by exerting pressure, the structuring taking place by a continuous movement of the mask parallel to the surface of the product and/or by a continuous movement of said product parallel to the surface of the product. The speed of movement and the duration of contact, under pressure between the product and the mask are adjusted according to the nature of the surface to be structured, in particular:
its viscosity and its surface tension;
possibly the type of features desired (most faithful reproduction of the pattern on the mask, or an intentionally truncated reproduction, etc.).

The pattern on the mask is not necessarily the negative of the pattern replicated. Thus, the final pattern may be formed using several masks or by several passes.

The mask may have zones with pattern features differing by their size (both width and height) and/or their orientation and/or their distance.

Another possible process for fabricating the grating according to the invention comprises photolithography. This process generally consists in firstly providing the transparent substrate with a first layer in which said features in relief will be formed. This first layer is comparable to the deposited sol-gel or polymer layer of the embossing process. It may also be of the same nature as the latter, especially made of silica. In a second step of the process, a second layer, of a photosensitive resin or photoresist, is deposited. This is cured at defined locations by exposure to a specific radiation. Thus, a mask is formed on top of the first layer to be etched, after the uncured parts of the photosensitive resin have been removed. Next, etching is carried out in the same way as described above relating to the optional step of the embossing process. Possible residues of the photosensitive resin may be removed.

Another process for fabricating the grating according to the invention comprises the transfer of a nanostructured layer. A layer bonded to a first support is bonded to a second, so as to constitute a device according to the invention. The layer may be made of a plastic or the like.

Another process that can be used relies on ion exchange, for example Na⁺ ions exchanged by Ag⁺ ions in a mineral glass.

Finally, a photorefractive effect may be used in which modulated light induces a spatial modulation of the refractive index of the material (for example, photorefractive crystal made of barium titanate). It is also possible to use an electrooptic effect, in which an electric field induces a spatial modulation of the refractive index of the material.

Depending on the form of the structuring intended, this process may not necessarily lead to perfect geometric shapes. In particular in the case of sharply-angled features, these may be rounded without impairing the required performance.

According to a first embodiment variant, a profile of “fly's eye” type is produced, whereby the plurality of periodic or aperiodic features in relief have the following geometric characteristics: the pitch w and the height h of the feature satisfy the following relationships:
w≦λ, preferably w≦λ/2 and more preferably w≦λ/4; and h≧λ/4, preferably h≧λ and more preferably h≧2λ.

In this configuration, λ falls within the solar spectrum and more particularly is located at the maximum efficiency of the solar cell, notably λ=500 nm in the case of amorphous silicon (cf FIG. 3) and λ=700 nm in the case of microcrystalline silicon (cf. FIG. 3).

The features may for example have the shape of a cone or a pyramid with a polygonal, such as triangular, square, rectangular, hexagonal or octagonal, base, said features possibly being convex, i.e. as excrescences relative to the general plane of the interface layer, or may be concave, i.e. as hollows in the thickness of the interface layer.

All these features may extend over the surface and form parallel or nonparallel lines (in fact they may generate studs).

The material chosen to form the material of the interface layer has a refractive index substantially similar or close to that of the material constituting the substrate having a glass function (about 1.50).

A conductive layer 3 called TCO (transparent conductive oxide) layer, is deposited on this interface layer 2. It may be chosen from the following materials: doped tin oxide, notably doped with fluorine or with antimony (the precursors that can be used in the case of CVD deposition may be tin halides or organometallics associated with a fluorine precursor of the hydrofluoric acid or trifluoroacetic acid type), doped zinc oxide, notably doped with aluminum (the precursors that can be used in the case of CVD deposition may be zinc and aluminum halides or organometallics) or else doped indium oxide, notably doped with tin (the precursors that can be used in the case of CVD deposition may be tin and indium halides or organometallics).

The conductive layer 3 has a resistance per square of at most 30 ohms per square, notably at most 20 ohms per square and preferably at most 10 or 15 ohms per square. It is generally between 5 and 12 ohms per square.

It may be noted that the interface layer has an index n such that n_{glass}≦n≦n_{TCO} if the interface layer is placed between the glass and the TCO conductive layer 3.

An antireflection effect will be obtained in this way between the substrate 1 having a glass function (based on glass) and the conductive layer 3. This results in an increase in transmission of around 2 to 3% for a conventional TCO of index close to 2.0.

The conductive layer 3 is covered with a functional layer 4 of a solar cell.

It is possible to obtain various optical properties within the solar cell depending on the nature of the contact zone between the conductive layer 3 and the functional layer 4:
if the contact zone is conforming, i.e. the conductive layer 3 conforms to the geometry of the interface layer 2 coming from the relief features, a second antireflection effect is obtained between the conductive layer 3 and the functional layer 4. For a TCO of index 2 and a functional layer of index 3, the increase in transmission will be around 3 to 4%;
if the contact zone is not conforming, i.e. the conductive layer 3 has a different texturing (for example formation of grains) from that of the interface layer 2, this second texture may assist in light trapping and make it possible to lengthen a path of the light in the functional layer of the solar cell.

According to a second embodiment variant, a structure that diffuses or diffracts the light is produced. The textured part of the interface layer 2 comprises a plurality of periodic or aperiodic features in relief which have the following geometric characteristics: the pitch w and the height h satisfy the following relationships: λ/4≦w≦2λ; and h is between 20 nm and 1 μm, preferably between 30 nm and 500 nm and more preferably h is between 50 nm and 200 nm.

In this configuration, the chosen wavelength λ corresponds to a wavelength in which the solar spectrum has a large amplitude but the conversion efficiency of the cell is not its optimum. In this way, the wavelengths travel a longer distance in the solar cell and the probability of being converted is higher. Wavelengths will be chosen for which the conversion efficiency is not too low, because if λ values are taken for which the conversion efficiency is too low, the fact of extending the optical path will entail a large relative increase but a small absolute increase. To give an example in the case of solar cells based on amorphous silicon (cf. FIG. 3), λ will be chosen to be between 550 and 750 nm (above this value, the efficiency is too low). In the case of microcrystalline silicon (cf. FIG. 3), λ will be chosen to be between 500 and 650 nm and between 800 and 1000 nm.

The features may for example have the shape of a cone or a pyramid with a polygonal, such as triangular, square, rectangular, hexagonal or octagonal, base, said features possibly being convex, i.e. as excrescences relative to the general plane of the interface layer, or may be concave, i.e. as hollows in the thickness of the interface layer.

All these features may extend over the surface and form parallel or nonparallel lines (in fact they may generate studs).

A conductive layer 3 called TCO (transparent conductive oxide) layer, is deposited on this interface layer 2. It may be chosen from the following materials: doped tin oxide, notably doped with fluorine and or with antimony (the precursors that can be used in the case of CVD deposition may be tin halides or organometallics associated with a fluorine precursor of the hydrofluoric acid or trifluoroacetic acid type), doped zinc oxide, notably doped with aluminum (the precursors that can be used in the case of CVD deposition may be zinc and aluminum halides or organometallics) or else doped indium oxide, notably doped with tin (the precursors that can be used in the case of CVD deposition may be tin and indium halides or organometallics).

The conductive layer 3 has a resistance per square of at most 30 ohms per square, notably at most 20 ohms per square and preferably at most 10 or 15 ohms per square. It is generally between 5 and 12 ohms per square.

The conductive layer 3 is covered with a functional layer 4 of a solar cell. A diffracting effect is produced, the light rays are diffused or diffracted at the interface layer.

If the conductive layer 3 conforms to the texturing coming from the interface layer and in addition has a certain intrinsic roughness, then, in this case, the interface zone between the conductive layer 3 and the functional layer 4 will have texturing on two scales, a first scale being given by the textured interface layer and the second scale coming from the intrinsic roughness of the conductive layer. This roughness on two scales makes it possible to improve the light trapping.

For certain modes, the roughness is nonuniform, or random. There are no regular features on the surface of the interface layer and of the conductive layer, but variable sizes of excrescences and/or hollows on the surface of the layers randomly distributed over the entire said surface. This roughness will already allow substantial diffusion or scattering of the light transmitted by the substrate, predominantly “forward” scattering, i.e. to diffuse the light but predominantly toward the interior of the solar cell.

The aim is, here again, to optimally “trap” the incident solar rays in specific wavelengths λ. For cells based on amorphous silicon, λ will be chosen to between 550 and 750 nm and for those based on microcrystalline silicon (cf. FIG. 3), λ will be chosen to be between 500 and 650 nm and between 800 and 1000 nm.

The functional layer 4 is covered with a conductive layer 5 that has to serve as second electrode for the solar module. This conductive layer 5, for example made of silver, may be produced by a vacuum (magnetron) sputtering technique.

Next, this glass plate 1 provided with all of the abovementioned layers is fastened via a lamination interlayer or encapsulant 6 to a back glass plate 7, thus making up a solar or photovoltaic cell.

FIG. 2 shows another embodiment of the invention that differs from that illustrated in FIG. 1 simply by the position of the interface layer 2 relative to the substrate.

In this embodiment, the interface layer 2 is on the face A of the substrate 1. In this case, the interface layer has a refractive index n≦n_{glass}. It allows the incident light to be diffused or diffracted so that the light rays travel through the substrate 1, then through the conductive layer 3 and then the functional layer 4, at high angles of incidence, thus making it possible to increase the light trapping phenomenon. This light diffusion or diffraction is obtained for specific wavelengths.

Relief features will be used that have a pitch w and a height h that satisfy the following relationships: λ/4≦w≦2λ and h is between 20 nm and 1 μm, preferably between 30 nm and 500 nm and more preferably h is between 50 nm and 200 nm. λ will be chosen to be between 550 and 750 nm (the efficiency beyond this value is too low) in the case of amorphous silicon. For polycrystalline silicon (cf. FIG. 3) λ will be chosen between 500 and 650 nm and between 800 and 1000 nm.

The substrate according to the invention can be used within a solar cell.

Depending on the intended application, it is possible to apply, on the most appropriate face of the plate, at least one layer giving the latter a particular property. A layer forming a barrier at certain wavelengths, for example in the ultraviolet, may notably be applied. It is also possible to apply on the plate, preferably at least on the side directly in the ambient air, an antisoiling layer, such as a TiO₂ layer, especially a layer forming the subject of patent application EP 1 087 916, or an antisoiling layer made of SiO₂ or silicon oxycarbide or silicon oxynitride or silicon oxycarbon nitride, as described in WO 01/32578.

### EXAMPLE 1

FIG. 4 illustrates a “fly's eye” antireflection configuration according to the first embodiment variant.

An interface layer 2 is deposited on face B of a glass substrate 1. This layer 2 is structured and has grooves with a trapezoidal base. The bases of the trapezoids have a width w=135 nm and p=15 nm. The grooves are spaced apart by a distance p=15 nm. The depth h of the feature is 900 nm.

A transparent conductive layer 3 is deposited on this interface layer 2.

Table 1 gives the values of the reflection between the glass substrate and the conductive layer 3, with the interface layer 2 present and without this interface layer 2. The reflection indices are, respectively: n=1.52 for the glass 1; n=1.52 for the structured interface layer 2; and n=2.01 for the conductive (TCO) layer 3. The reflection was calculated for three angles of incidence θ: 0°, 30° and 42° (the latter angle being the angle of total internal reflection in the glass) and for a wavelength λ=450 nm (ideal for a cell of the amorphous silicon type).

TABLE 1
Reflection at the glass/conductive layer
interface in the presence of an interface layer 2
having an antireflection effect (“fly's eye” structured
layer) and in the absence of said interface layer.

| | R(θ = 0°) | R(θ = 30°) | R(θ = 42°) |
|---|---|---|---|
| Interface | 0.08% | 0.04% | 0.02% |
| layer: | | | |
| h = 900 nm | | | |
| No interface | 1.93% | 1.95% | 1.97% |
| layer | | | |

The antireflection effect of the interface layer is obvious, with a reflection that goes from about 2% to less than 0.1% for all the angles of incidence.

### EXAMPLE 2

Example 2 illustrates the second embodiment variant of the invention, namely that in which the optical path is increased. Referring to FIGS. 5 and 6, an interface layer 2 is deposited on face B of a glass substrate 1. This interface layer 2 is structured and has grooves with a sinusoidal profile. The pitch of the sinusoid is w and the height h. Deposited on this interface layer 2 is a transparent conductive layer 3 forming a TCO of thickness e, which conforms to the structuring of the textured interface layer 2. An increase in the path of the light in the functional layer 4 is thus obtained. If a light ray is in the functional layer 4 with an angle θ relative to the normal to the cell, the optical path in the active medium will increase by a factor 1/cos θ relative to a ray normal to the cell.

Given below is the increase in optical path as a function of the wavelength λ of the light for various texture pitches w. The height h was set at h=200 nm and the thickness e=600 nm.

Given below is the increase A (in %) of the optical path as a function of the wavelength λ of the light in the functional layer 4 for various pitches w of the texture. The indices are n=1.52 for the media 1 and 2 (glass and textured interface layer), n=2.0 for the medium 3 (TCO) and n=3 for the medium 4 (functional layer 4). The increase A (in %) was calculated by averaging over a range of angles of incidence in air between 0° and 50°.

The results are given in FIG. 6. This shows an increase in the optical path due to the diffraction/scattering of the light on the structured layers. The increase in optical path, i.e. the light trapping, varies with the wavelength of the light. In particular a texture with w=300 nm is particularly effective for a cell of the amorphous silicon type, such as that in FIG. 3. Indeed, the light trapping is particularly effective for λ between 600 and 750 nm. Moreover, a texture with w=400 nm appears to be particularly effective for a cell of the microcrystalline silicon type, such as that in FIG. 3. Indeed, the light trapping is particularly effective for λ between 500 and 650 nm and between 750 and 900 nm, whereas the light trapping is less effective around 700 nm, the wavelength at which this cell possesses an optimum conversion efficiency, making the light trapping effect less necessary.

### EXAMPLE 3

Finally example 3 shows a structure which has both a “fly's eye” antireflection effect and a light trapping effect.

In this example 3, we adopt the geometry of example 2 and in particular the case with w=300 nm. In this configuration, not only is it possible to obtain light trapping with an increase in the optical path but also an antireflection effect is obtained between the glass (medium 1) and the functional layer 4. By calculating the light transmission between the medium 1 (glass) and the functional layer 4, for a first wavelength range between λ=400 and 600 nm for such a structure, an increase in the light transmission of around 4% is obtained (this value being obtained by averaging over angles of incidence between 0° and 50°). Moreover we have already seen (cf. FIG. 6) that this structure allows the optical path to be increased by around 20% for a second wavelength range between 600 and 750 nm. It follows that this structure has two beneficial effects for a functional layer 4 of amorphous silicon type, such as that in FIG. 3. For wavelengths between 400 and 600 nm, for which the functional layer 4 is very effective, the structure induces an antireflection effect, whereas for wavelengths between 600 and 750 nm, in which the functional layer 4 is less effective, a light trapping effect is obtained.

1. A substrate having a glass function, combined with a textured electrode comprising at least one transparent conductive layer based on one or more metal oxides, said layer being covered with at least one functional layer of an element capable of collecting light, wherein the substrate is covered with an interface layer having a textured part comprising a repetition of periodic or aperiodic features in relief.

2. The substrate as claimed in claim 1, wherein the interface layer is located on the rear face of the substrate and has a textured part that comprises a repetition of periodic or aperiodic features in relief, of pitch w and height h satisfying the following relationships: w≦λ; and h≧λ/4, where λ falls within the solar spectrum and is located at the maximum energy conversion efficiency of a solar cell.

3. The substrate as claimed in claim 1, wherein the interface layer is located on the rear face of the substrate and has a textured part that comprises a repetition of periodic or aperiodic features in relief, of pitch w and height h satisfying the following relationships: λ/4≦w≦2λ; and h is between 20 nm and 1 μm, where λ is located at a wavelength at which the solar spectrum has a large amplitude but the conversion efficiency of a cell is not its optimum.

4. The substrate as claimed in claim 1, wherein the conductive layer is deposited on the interface layer.

5. The substrate as claimed in claim 1, wherein the interface layer is located on the front face of the substrate and has a textured part that comprises a repetition of periodic or aperiodic features in relief, of pitch w and height h satisfying the following relationships: λ/4≦w≦2λ; and h is between 20 nm and 1 μm, where λ is located at a wavelength at which the solar spectrum has a large amplitude but the conversion efficiency of a cell is not its optimum.

6. The substrate as claimed in claim 1, wherein the conductive layer conforms to the interface layer.

7. The substrate as claimed in claim 1, wherein the conductive layer has a different roughness from that of the interface layer.

8. The substrate as claimed in claim 1, wherein the interface layer has a refractive index close to that of the substrate.

9. The substrate as claimed in claim 5, wherein the interface layer has a refractive index n≦n_{substrate}.

10. The substrate as claimed in claim 1, wherein the interface layer has a refractive index n such that n_{substrate}≦n≦n_{TCO} if the interface layer is placed between the substrate and the conductive layer.

11. The substrate as claimed in claim 1, wherein the features in relief comprise parallel lines.

12. The substrate as claimed in claim 1, wherein the features in relief comprise nonparallel lines and/or studs.

13. The substrate as claimed in claim 1, wherein it is combined with a solar module, the textured face being directed toward the active material of the solar module.

14. The substrate as claimed in claim 1, wherein the interface layer is located on the rear face of the substrate and has a textured part which comprises a repetition of periodic or aperiodic features, of pitch w substantially close to 300 nm, for which it has a combination of an antireflection effect for a first wavelength range and a light trapping effect for a second wavelength range.

15. A process for producing a substrate as claimed in claim 1, wherein the textured surface is obtained by embossing a sol-gel or polymer layer.

16. A process for producing a substrate as claimed in claim 1, wherein the textured surface is obtained by a photolithography technique.

17. (canceled)

18. A solar cell, comprising the substrate as claimed in claim 1.
